(19) United States
(12) Patent Application Publication
(10) Pub. No.: US 2026/0156888 A1
(43) Pub. Date: Jun. 4, 2026

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Shinichiro MATSUNAGA, Matsumoto-city (JP); Shinsuke HARADA, Tsukuba-shi (JP)

(73) Assignee: FUJI ELECTRIC CO., LTD., Kawasaki-shi (JP)

(21) Appl. No.: 19/373,248

(22) Filed: Oct. 29, 2025

(30) Foreign Application Priority Data
Dec. 2, 2024 (JP) 2024-209320

(51) Int. Cl. H10D 62/832; H10D 30/01; H10D 30/66; H10D 62/10; H10D 62/60; H10D 62/834

(52) U.S. Cl. CPC H10D 62/8325; H10D 30/0297; H10D 30/668; H10D 62/102; H10D 62/126; H10D 62/60; H10D 62/834

(57) ABSTRACT

A silicon carbide semiconductor device, including: a semiconductor substrate, a first semiconductor region, a second semiconductor region, a plurality of third semiconductor regions; a plurality of fourth semiconductor regions; a plurality of fifth semiconductor regions; a plurality of trenches penetrating through the third semiconductor regions and the second semiconductor region and reaching the first semiconductor region; a plurality of gate electrodes provided in the plurality of trenches, via a plurality of gate insulating films, respectively; a first electrode connected to the fourth semiconductor regions and the third semiconductor regions; and a second electrode provided at a second main surface of the semiconductor substrate. The fifth semiconductor regions separates the second semiconductor region into first second-semiconductor-regions and second second-semiconductor-regions, each first second-semiconductor-region, but not second second-semiconductor-region, being directly adjacent to one of the gate insulating films. A thickness of each first second-semiconductor-region is in a range of 30 nm to 100 nm.

### CROSS REFERENCE TO RELATED APPLICATIONS

This application is based upon and claims the benefit of priority of the prior Japanese Patent Application No. 2024-209320, filed on Dec. 2, 2024, the entire contents of which are incorporated herein by reference.

### BACKGROUND OF THE INVENTION

### 1. Field of the Invention

Embodiments of the disclosure relate to a silicon carbide semiconductor device and a method of manufacturing a silicon carbide semiconductor device.

### 2. Description of the Related Art

Japanese Laid-Open Patent Publication No. 2003-60203 and Japanese Laid-Open Patent Publication No. 2003-31802 each describe a silicon carbide semiconductor device having a dopant profile of SiO₂/p-type/n-type/p-type near an interface of a gate insulating film.

### SUMMARY OF THE INVENTION

A silicon carbide semiconductor device according to an embodiment of the present disclosure includes: a semiconductor substrate containing silicon carbide, the semiconductor substrate having a first main surface and a second main surface opposite to each other; a first semiconductor region of a first conductivity type, provided in the semiconductor substrate; a second semiconductor region of a second conductivity type, provided between the first main surface of the semiconductor substrate and the first semiconductor region; a plurality of third semiconductor regions of the first conductivity type, provided selectively between the first main surface of the semiconductor substrate and the second semiconductor region; a plurality of fourth semiconductor regions of the second conductivity type, provided selectively between the first main surface of the semiconductor substrate and the second semiconductor region, a dopant concentration of the plurality of fourth semiconductor regions being higher than a dopant concentration of the second semiconductor region; a plurality of fifth semiconductor regions of the first conductivity type, provided selectively in the second semiconductor region; a plurality of trenches penetrating through the plurality of third semiconductor regions and the plurality of second semiconductor region and reaching the first semiconductor region; a plurality of gate insulating films in the plurality of trenches, respectively; a plurality of gate electrodes provided in the plurality of trenches, via the plurality of gate insulating films, respectively; a first electrode connected to the plurality of fourth semiconductor regions and the plurality of third semiconductor regions; and a second electrode provided at the second main surface of the semiconductor substrate. The plurality of fifth semiconductor regions separates the second semiconductor region into a plurality of first second-semiconductor-regions that are relatively closer to the plurality of gate insulating films and a plurality of second second-semiconductor-regions that are relatively farther from the plurality of gate insulating films, and a thickness of each of the plurality of first second-semiconductor-regions is in a range of 30 nm to 100 nm, a carrier concentration of the plurality of fifth semiconductor regions is controlled by a potential of the plurality of gate electrodes, and a current between the first electrode and the second electrode is controlled by controlling the carrier concentration.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to a first embodiment.

FIG. 2 is a graph depicting an effect of the silicon carbide semiconductor device according to the first embodiment.

FIG. 3 is a cross-sectional view schematically depicting a state of the silicon carbide semiconductor device according to the first embodiment during manufacture.

FIG. 4 is a cross-sectional view schematically depicting a state of the silicon carbide semiconductor device according to the first embodiment during manufacture.

FIG. 5 is a cross-sectional view schematically depicting a state of the silicon carbide semiconductor device according to the first embodiment during manufacture.

FIG. 6 is a cross-sectional view schematically depicting a state of the silicon carbide semiconductor device according to the first embodiment during manufacture.

FIG. 7 is a cross-sectional view schematically depicting a state of the silicon carbide semiconductor device according to the first embodiment during manufacture.

FIG. 8 is a cross-sectional view depicting a structure of the silicon carbide semiconductor device according to a second embodiment.

FIG. 9 is a top view depicting the structure of the semiconductor device according to the second embodiment.

### DETAILED DESCRIPTION OF THE INVENTION

First, problems associated with the conventional techniques are discussed. In an instance of Japanese Laid-Open Patent Publication No. 2003-60203, when sufficient bias is applied to a gate, not a trench structure, carrier electrons are attracted to an inversion layer occurring at an interface of an oxide film and thus, the channel is not completely apart from the interface of the oxide film. Further, in an instance of Japanese Laid-Open Patent Publication No. 2003-31802, during on-operation, the operating principle of applying a negative bias to the gate is different from MOS operation of the present proposal.

An outline of an embodiment of the present disclosure is described. (1) A silicon carbide semiconductor device according to one aspect of the present disclosure is as follows. The silicon carbide semiconductor device includes: a first semiconductor region of a first conductivity type, provided in a semiconductor substrate containing silicon carbide; a second semiconductor region of a second conductivity type provided between a first main surface of the semiconductor substrate and the first semiconductor region; a plurality of third semiconductor regions of the first conductivity type, provided selectively between the first main surface of the semiconductor substrate and the second semiconductor region; a plurality of fourth semiconductor regions of the second conductivity type, provided selectively between the first main surface of the semiconductor substrate and the second semiconductor region, and having a dopant concentration higher than that of the second semiconductor region; a plurality of fifth semiconductor regions of the first conductivity type, provided selectively in the second semiconductor region; a plurality of trenches penetrating through the plurality of third semiconductor regions and the second semiconductor region and reaching the first semiconductor region; a plurality of gate electrodes provided in the plurality of trenches, via a plurality of gate insulating films, respectively; a first electrode connected to the plurality of fourth semiconductor regions and the plurality of third semiconductor regions; and a second electrode provided at a second main surface of the semiconductor substrate. The plurality of fifth semiconductor regions separates the second semiconductor region into a plurality of first second-semiconductor-regions that are relatively closer to the plurality of gate insulating films and a plurality of second second-semiconductor-regions that are relatively farther from the plurality of gate insulating films. A thickness of each of the plurality of first second-semiconductor-regions is in a range of 30 nm to 100 nm, a carrier concentration of the plurality of fifth semiconductor regions is controlled by a potential of the plurality of gate electrodes, and a current between the first electrode and the second electrode is controlled by controlling the carrier concentration.

According to the disclosure above, a dopant profile near an interface of a gate insulating film is set to be SiO₂/p-type/n-type/p-type. As a result, near the gate insulating film interface, an embedded channel with high mobility is apart from a channel with low mobility near the interface. Thus, carriers of the embedded channel are not attracted to the channel with low mobility near the interface and the isolated embedded channel may reduce channel resistance and maintain a lower on-resistance and higher mobility as compared to a conventional inversion carrier channel.

(2) Further, in the silicon carbide semiconductor device according to the present disclosure, in (1) above, the plurality of fifth semiconductor regions may be in contact with the plurality of third semiconductor regions and the first semiconductor region.

(3) Further, in the silicon carbide semiconductor device according to the present disclosure, in (1) or (2) above, ends of the plurality of first second-semiconductor-regions in a direction in which the plurality of trenches extend may be connected to ends of the plurality of second second-semiconductor-regions in the direction in which the plurality of trenches extend.

(4) Further, in the silicon carbide semiconductor device according to the present disclosure, in any one of (1) to (3) above, the second conductivity type is a p-type, and the potential of the plurality of gate electrodes may be controlled to be positive with respect to the first electrode, thereby controlling the carrier concentration of the plurality of fifth semiconductor regions to be in a conductive state.

(5) Further, in the silicon carbide semiconductor device according to the present disclosure, in any one of (1) to (4) above, an off-state may be entered with a voltage of the plurality of gate electrodes being a same voltage as that of the first electrode.

(6) A silicon carbide semiconductor device according to one aspect of the present disclosure is as follows. The silicon carbide semiconductor device includes: a first semiconductor region of a first conductivity type, provided in a semiconductor substrate containing silicon carbide; a second semiconductor region of a second conductivity type provided between a first main surface of the semiconductor substrate and the first semiconductor region; a plurality of third semiconductor regions of the first conductivity type, provided selectively between the first main surface of the semiconductor substrate and the second semiconductor region; a plurality of fourth semiconductor regions of the second conductivity type, provided selectively between the first main surface of the semiconductor substrate and the second semiconductor region, and having a dopant concentration higher than that of the second semiconductor region; a plurality of fifth semiconductor regions of the first conductivity type, provided selectively in the second semiconductor region; a plurality of trenches penetrating through the plurality of third semiconductor regions and the second semiconductor region and reaching the first semiconductor region; a plurality of gate electrodes provided in the plurality of trenches, via a plurality of gate insulating films, respectively; a first electrode connected to the plurality of fourth semiconductor regions and the plurality of third semiconductor regions; and a second electrode provided at a second main surface of the semiconductor substrate. The silicon carbide semiconductor device has a double gate structure in which one channel formed in an entire area of the second semiconductor region between adjacent two of the plurality of trenches, is sandwiched from both side surfaces thereof, by the adjacent two of the plurality of trenches, each of the plurality of fifth semiconductor regions separates the second semiconductor region into a first second-semiconductor-region (3a) that is relatively closer to a first of the plurality of gate insulating films, of a first of the adjacent two of the plurality of trenches and a second second-semiconductor-region (3b) that is relatively closer to a second of the plurality of gate insulating films, of a second of the adjacent two of the plurality of trenches.

(7) A method of manufacturing a silicon carbide semiconductor device according to the present disclosure is as follows. First, as a first process, a semiconductor substrate containing silicon carbide, and having a first main surface and a second main surface opposite to each other is prepared and a first semiconductor region of a first conductivity type is formed in the semiconductor substrate. Next, as a second process, a second semiconductor region of a second conductivity type is formed between the first main surface of the semiconductor substrate and the first semiconductor region. Next, as a third process, a plurality of third semiconductor regions of the first conductivity type is selectively formed between the first main surface of the semiconductor substrate and the second semiconductor region. Next, as a fourth process, a plurality of fourth semiconductor regions of the second conductivity type is selectively formed between the first main surface of the semiconductor substrate and the second semiconductor region, a dopant concentration of the plurality of fourth semiconductor regions being higher than dopant concentration of the second semiconductor region. Next, as a fifth process, a plurality of trenches penetrating through the plurality of third semiconductor regions and the second semiconductor region and reaching the first semiconductor region is formed. Next, as a sixth process, a plurality of fifth semiconductor regions of the first conductivity type is selectively formed in the second semiconductor region. Next, as a seventh process, a plurality of gate insulating films is formed in the plurality of trenches, respectively. Next, as an eighth process, a plurality of gate electrodes is formed in the plurality of trenches, via the plurality of gate insulating films, respectively. Next, as a ninth process, a first electrode electrically connected to the plurality of fourth semiconductor regions and the plurality of third semiconductor regions is formed. Next, as a tenth process, a second electrode is formed at the second main surface of the semiconductor substrate. Each of the plurality of fifth semiconductor regions separates the second semiconductor region into a first second-semiconductor-region (3a) relatively closer to a first adjacent one of the plurality of gate insulating films, of a first adjacent one of the plurality of trenches and a second second-semiconductor-region (3b) relatively closer to a second adjacent one of the plurality of gate insulating films, of a second adjacent one of the plurality of trenches, and in the sixth process, a thickness of each of the plurality of first second-semiconductor-regions is in a range of 30 nm to 100 nm, a carrier concentration of the plurality of fifth semiconductor regions is controlled by a potential of the plurality of gate electrodes, and a current between the first electrode and the second electrode is controlled by controlling the carrier concentration.

(8) Further, in the method of manufacturing the silicon carbide semiconductor device according to the present disclosure, in (7) above, the sixth process may include obliquely implanting phosphorus ions at an angle in a range of 15 degrees to 60 degrees with respect to sidewalls of the plurality of trenches, thereby forming the plurality of fifth semiconductor regions.

(9) Further, in the method of manufacturing the silicon carbide semiconductor device according to the present disclosure, in (7) above, the sixth process may include obliquely implanting arsenic ions at an angle in a range of 15 degrees to 60 degrees with respect to sidewalls of the plurality of trenches, thereby forming the plurality of fifth semiconductor regions.

(10) Further, the method of manufacturing the silicon carbide semiconductor device according to the present disclosure, in any one of (7) to (9) above, may further include as an eleventh process, obliquely implanting aluminum ions in the plurality of first second-semiconductor-regions, at an angle in a range of 15 degrees to 60 degrees with respect to sidewalls of the plurality of trenches.

Findings underlying the present disclosure are discussed. First, problems associated with a conventional silicon carbide semiconductor device are discussed. A structure of a conventional silicon carbide semiconductor device is described taking a trench-type MOSFET as an example. In the trench-type MOSFET, an n⁺-type buffer layer and an n-type silicon carbide epitaxial layer are stacked at a front surface of an n⁺-type starting substrate. At a first surface of the n-type silicon carbide epitaxial layer, opposite to a second surface thereof facing the n⁺-type starting substate, an n-type high-concentration region is provided. Further, at a first surface of the n-type high-concentration region, opposite to a second surface thereof facing the n⁺-type starting substrate, first p⁺-type base regions are selectively provided. In the n-type high-concentration region, second p⁺-type base regions are selectively provided so as to underlie the entire bottom of each trench.

Further, in the conventional trench-type MOSFET, a p-type base region, n⁺-type source regions, p⁺⁺-type contact regions, gate insulating films, gate electrodes, an interlayer insulating film, ohmic electrodes (source electrodes), a back electrode, trenches, a source electrode pad, and a trench electrode pad are further provided. The ohmic electrodes are provided on the n⁺-type source regions and the p⁺⁺-type contact regions, and the source electrode pad is provided on the ohmic electrodes.

Further, between the ohmic electrodes, the interlayer insulating film, and the source electrode pad, for example, a barrier metal that prevents diffusion of metal atoms in a direction from the ohmic electrodes to the gate electrodes is provided.

In the conventional silicon carbide semiconductor device, a dopant profile near an interface of a gate insulating film is set to be SiO₂/p-type/n-type/p-type. As a result, vertical field strength of a channel near the interface of the gate insulating film may be reduced as compared to a simple inversion layer channel. Further, while mobility is extremely low very close to the interface of the gate insulating film (about 30 nm) due to a trap and/or trapped charge, the vertical field strength is reduced thereby enabling mobility of carriers even at locations apart from the interface, whereby carrier mobility may be increased in the channel overall.

However, in Japanese Laid-Open Patent Publication No. 2003-60203, disclosed experimental results indicate that a concentration of a p-type region on the interface side of the gate insulating film is low and when gate voltage increases, the channel is not completely isolated, whereby mobility drops and ultimately, an inversion layer occurs. Furthermore, the disclosed experimental results exhibit substantially depression (about a threshold 0V). Further, in Japanese Laid-Open Patent Publication No. 2003-31802, while a p-type region on the interface side of the gate insulating film is called a gate p region, connection to the source electrodes is not clear. While on-operation is achieved by making the (polysilicon) gate electrode negative to cause holes to accumulate in the p-type region and thereby make the n embedded layer conductive, the operating principle is different from that of the present proposal.

Embodiments of a silicon carbide semiconductor device and a method of manufacturing a silicon carbide semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and will not be repeatedly described.

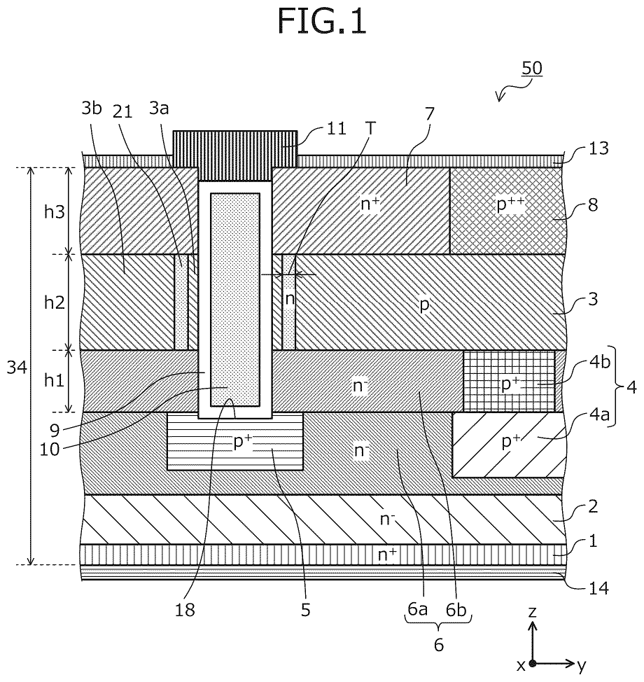

A silicon carbide semiconductor device and a method of manufacturing the silicon carbide semiconductor device according to a first embodiment solving the problems above are described. FIG. 1 is a cross-sectional view depicting a structure of the silicon carbide semiconductor device according to the first embodiment. In FIG. 1, only an active region through which a main current of the trench-type MOSFET 50 flows is depicted.

As depicted in FIG. 1, a silicon carbide semiconductor substrate 34 is formed by epitaxially growing, at a front surface of an n⁺-type starting substrate 1 containing Si, epitaxial layers constituting, respectively, a first n⁻-type silicon carbide epitaxial layer (first semiconductor region of a first conductivity type) 2 and a p-type base layer (second semiconductor region of a second conductivity type) 3 are formed in the sequence stated.

The n⁺-type starting substrate 1 is a silicon carbide single crystal substrate doped with, for example, nitrogen (N). The first n⁻-type silicon carbide epitaxial layer 2 has a dopant concentration that is lower than a dopant concentration of the n⁺-type starting substrate 1 and the first n⁻-type silicon carbide epitaxial layer 2 is, for example, a low-concentration n⁻type drift layer doped with nitrogen. At a first surface of the first n⁻-type silicon carbide epitaxial layer 2, opposite to a second surface thereof facing the n⁺-type starting substrate 1, a second n⁻-type silicon carbide layer 6 is formed. The second n—type silicon carbide layer 6 is constituted by a lower second n⁻-type silicon carbide layer 6a in which later-described lower first p⁺-type regions 4a are provided and an upper second n⁻-type silicon carbide layer 6b provided above the lower second n⁻-type silicon carbide layer 6a. The second n⁻-type silicon carbide layer 6 has a dopant concentration that is lower than the dopant concentration of the n⁺-type starting substrate 1 and higher than the dopant concentration of the first n⁻type silicon carbide epitaxial layer 2; for example, the second n⁻-type silicon carbide layer 6 is a high-concentration n⁻-type drift layer doped with nitrogen. Hereinafter, the n⁺-type starting substrate 1, the first n⁻-type silicon carbide epitaxial layer 2, the second n⁻-type silicon carbide layer 6, and the later-described p-type base layer 3 combined are assumed as a silicon carbide semiconductor substrate.

At a second main surface (back surface, i.e., back surface of the silicon carbide semiconductor substrate) of the n⁺-type starting substrate 1, a back electrode 14 (drain electrode) is provided. The back electrode 14 constitutes the drain electrode. At a surface of the back electrode, a trench electrode pad (not depicted) is provided.

In the silicon carbide semiconductor substrate, at a first main surface thereof (surface of the p-type base layer 3), a trench gate structure is formed. In particular, trenches 18 penetrate through n⁺-type source regions 7 and the p-type base layer 3, from the first main surface of the silicon carbide semiconductor substrate 34 and reach the second n⁻-type silicon carbide layer 6. Along inner walls of the trenches 18, gate insulating films 9 are formed along bottoms and sidewalls of the trenches 18 and on the gate insulating films 9 in the trenches 18, gate electrodes 10 are formed. The gate insulating films 9 insulate the gate electrodes 10 from the first n⁻-type silicon carbide epitaxial layer 2, the second n⁻-type silicon carbide layer 6, and the p-type base layer 3. A portion of each of the gate electrodes 10 may protrude toward a source electrode pad, from a top (side facing the source electrode pad) the trenches 18.

In the first n⁻-type silicon carbide epitaxial layer 2 and the second n⁻-type silicon carbide layer 6, first p⁺-type regions 4 and second p⁺-type regions 5 are selectively provided. The first p⁺-type regions 4 reach positions closer to the n⁺-type starting substrate 1 than are bottoms of the trenches 18. Each of the first p⁺-type regions 4 has a lower end (end facing the n⁺-type starting substrate 1) positioned closer to the n⁺-type starting substrate 1 than are the bottoms of the trenches 18. The first p⁺-type regions 4 are provided between the trenches 18. As depicted in FIG. 1, the first p⁺-type regions 4 are configured by the lower first p⁺-type regions 4a that are of a same height as the second p⁺-type regions 5, and upper first p⁺-type regions 4b provided, respectively, above the lower first p⁺-type regions 4a. The upper first p⁺-type regions 4b are provided in the second n⁻-type silicon carbide layer 6, at the surface thereof and each has an upper surface in contact with the p-type base layer 3.

Lower ends of the second p⁺-type regions 5 are positioned closer to the n⁺-type starting substrate 1 than are the bottoms of the trenches 18. The second p⁺-type regions 5 are formed, respectively, at positions facing the bottoms of the trenches 18 in a depth direction z. A width of each of the second p⁺-type regions 5 is wider than a width of each of the trenches 18. The bottoms of the trenches 18 may reach the second p⁺-type regions 5 or may be positioned in the second n⁻-type silicon carbide layer 6 between the p-type base layer 3 and the second p⁺-type regions 5 without being in contact with (being apart from) the second p⁺-type regions 5. The first p⁺-type regions 4 and the second p⁺-type regions 5 are doped with, for example, aluminum (Al).

Portions of the first p⁺-type regions 4 extend toward the trenches 18, thereby forming a structure in which the first p⁺-type regions 4 are connect to the second p⁺-type regions 5. In this instance, the portions of the first p⁺-type regions 4 may have, in a plan view, a layout in which the portions are disposed repeatedly alternating with the second n⁻type silicon carbide layer 6 in a direction x that is orthogonal to a direction y in which the first p⁺-type regions 4 and the second p⁺-type regions 5 are arranged. In other words, in the direction y, the first p⁺-type regions 4 and the second p⁺-type regions 5 may be partially connected at one or more locations. As a result, holes generated when avalanche breakdown occurs may be efficiently migrated to ohmic electrodes 13 by bonded portions of the second p⁺-type regions 5 and the first n⁻-type silicon carbide epitaxial layer 2 and the load on the gate insulating films 9 is reduced, whereby reliability is improved.

The p-type base layer 3 is provided at a surface of the first n⁻-type silicon carbide epitaxial layer 2, said surface facing the first main surface of the silicon carbide semiconductor substrate 34. A dopant concentration of the p-type base layer may be, for example, lower than that of the first p⁺-type regions 4. As a result, even when the concentration of the p-type base layer 3 is lowered to lower the threshold voltage, spreading of the depletion layer of the p-type base layer 3 is suppressed, whereby decreases in the breakdown voltage due to punch-through may be avoided. In the p-type base layer 3, at the surface thereof facing the first main surface of the silicon carbide semiconductor substrate 34, the n⁺-type source regions (third semiconductor regions of the first conductivity type) 7 and p⁺⁺-type contact regions (fourth semiconductor regions of a second conductivity type) 8 are selectively provided. Further, the n⁺-type source regions 7 and the p⁺⁺-type contact regions 8 are in contact with each other.

In the first embodiment, in the p-type base layer 3, along a direction in which the trenches 18 extend longitudinally, n-type embedded channels (fifth semiconductor regions of the first conductivity type) 21 are provided. Each of the n-type embedded channels 21 has an upper surface in contact with one of the n⁺-type source regions 7 and a lower surface in contact with the second n⁻-type silicon carbide layer 6. The n-type embedded channels 21 divide the p-type base layer 3 into first p-type base layer portions (first second-semiconductor-regions) 3a that are relatively closer to the gate insulating films 9 and second p-type base layer portions (second second-semiconductor-regions) 3b that are relatively farther from the gate insulating films 9. Ends of the first p-type base layer portions 3a and ends of the second p-type base layer portions 3b in the direction x in which the trenches 18 extend longitudinally are connected and thus, have a same potential. In other words, in the direction (the direction y) in which the trenches 18 are arranged, one each of: the gate insulating films 9, the first p-type base layer portions 3a, the n-type embedded channels 21, and the second p-type base layer portions 3b are repeatedly arranged sequentially in the order stated. Thus, the dopant profile in an orthogonal direction from a vicinity of an interface of any of the gate insulating films 9 is SiO₂/p-type/n-type/p-type.

As described, near the interfaces of the gate insulating films 9 are channel regions where channels with low mobility near the interfaces (the first p-type base layer portions 3a) and embedded channels with high mobility (the n-type embedded channels 21) are formed, isolated between directions in the trenches 18 extend. Thus, carriers of the embedded channels are not attracted to the interface channels, which have low mobility, and due to the separated embedded channels, the channel resistance is lower than that of the conventional inversion carrier channel and a low on-resistance and high mobility may be maintained. Furthermore, the embedded channels are separated along the direction in which the trenches 18 extend longitudinally and thus, vertical field mobility does not decrease with the operating gate voltage (2 MV to 3 MV/cm).

In the first embodiment, preferably, the dopant concentration of the n-type embedded channels 21 may be about 5×10¹⁷/cm³ and the dopant concentrations of the first p-type base layer portions 3a and the second p-type base layer portions 3b may be about 1×10¹⁸/cm³. Further, preferably, a height h1 of the upper second n⁻-type silicon carbide layer 6b may be about 0.5 μm or less, a height h2 of the p-type base layer 3 and the n-type embedded channels 21 may be about 0.5 μm or less, and a height h3 of the n⁺-type source regions 7 and the p⁺⁺-type contact regions 8 may be about 0.45 μm or less.

Further, as described hereinafter, the n-type embedded channels 21 are formed by obliquely implanting dopant ions (oblique implantation) and in particular, the first p-type base layer portions 3a relatively closer to the interface have a high concentration and a thickness in a range of about 30 nm to 100 nm, and a thickness T of the n-type embedded channels 21 is about 100 nm or less, whereby a threshold may be set to be 3 V or higher. Further, in the silicon carbide semiconductor device of the first embodiment, bias voltage, for example, 20V, positive from a source potential is applied to the gate electrodes 10, whereby a depletion layer formed between the first p-type base layer portions 3a and the n-type embedded channels 21 shrinks and the carrier concentration of the n-type embedded channels 21 becomes a donor concentration, thereby causing current to flow between the source electrodes 13 and the drain electrode 14. In contrast, when the source potential or a negative bias voltage is applied, a depletion layer occurs between the first p-type base layer portions 3a and the n-type embedded channels 21, the carrier concentration of the n-type embedded channels 21 decreases, and no current flows between the source electrodes 13 and the drain electrode 14. As described, current between the source electrodes 13 and the drain electrode 14 may be controlled by controlling the potential of the gate electrodes 10.

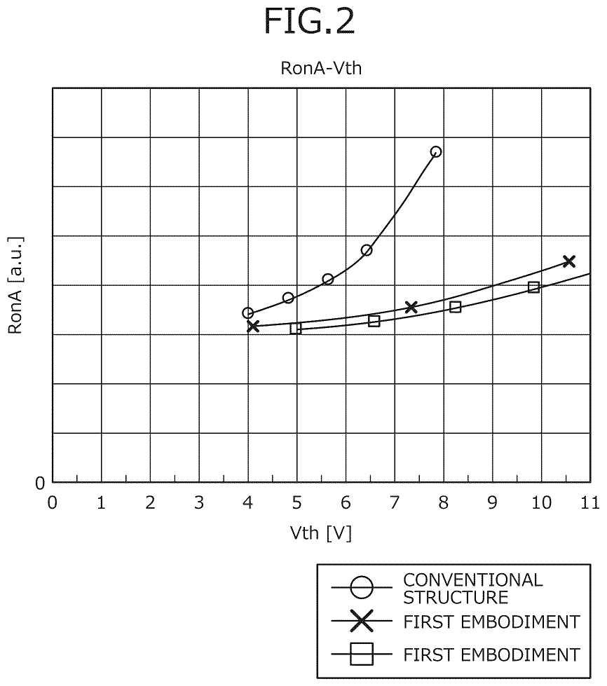

FIG. 2 is a graph depicting an effect of the silicon carbide semiconductor device according to the first embodiment. In FIG. 2, a vertical axis indicates RonA in units of mΩcm². A horizontal axis indicates Vth in units of V. In FIG. 2, “○” indicates an instance of a silicon carbide semiconductor device free of the conventional n-type embedded channels 21 and “×” and “□” indicate an instance of the silicon carbide semiconductor device according to the first embodiment. For, “×” and “□”, channel lengths differ, “×” is about 0.5 μm while “□” is about 0.4 μm. As depicted in FIG. 2, in the silicon carbide semiconductor device according to the first embodiment, channel mobility is increased, whereby a RonA-Vth tradeoff may be improved.

Further, preferably, the dopant concentration of the first p-type base layer portions 3a that are relatively closer to the gate insulating films 9 may be 1×10¹⁸/cm³ or higher, and the dopant concentration of the second p-type base layer portions 3b between the n-type embedded channels 21 relatively farther from the gate insulating films 9 may be 1×10¹⁸/cm³ or higher. As a result, the carrier concentration of the n-type embedded channels 21 is controlled and the gate electrodes 10 are set to have a positive potential with respect to the source electrodes 13, bringing about a conductive state and enabling an enhanced type in which the voltage of the gate electrodes 10 is a same voltage as that of the source electrodes 13 and an off-state is entered.

Preferably, a dopant of the n-type embedded channels 21 may be arsenic (As) or phosphorus (P). In particular, in an instance of arsenic (As), the n-type embedded channels 21 may be formed to have a narrower width and higher concentration and thus, is more preferable.

In FIG. 1, while only two trench MOS structures (metal-oxide-semiconductor insulated gates) are depicted, further MOS gate structures with a trench structure may be disposed in parallel.

An interlayer insulating film 11 is provided in an entire area of the first main surface of the silicon carbide semiconductor substrate, so as to cover the gate electrodes 10 embedded in the trenches 18. The ohmic electrodes (source electrodes) 13 are in contact with the n⁺-type source regions 7 and the p⁺⁺-type contact regions 8 via contact holes opened in the interlayer insulating film 11. The ohmic electrodes 13 are electrically insulated from the gate electrodes 10 by the interlayer insulating film 11. A source electrode pad (not depicted) is provided above the ohmic electrodes 13.

Further, between the ohmic electrodes 13, the interlayer insulating film 11, and the source electrode pad, for example, a barrier metal that prevents diffusion of metal atoms in a direction from the ohmic electrodes 13 to the gate electrodes 10 is provided. The barrier metal is formed by sequentially stacking a Ti film and a TiN film in the sequence stated and thereafter, a heat treatment is performed and thus, the Ti film is nitrified, becoming a TiN film.

Next, a method of manufacturing the silicon carbide semiconductor device according to the first embodiment is described. First, the silicon carbide semiconductor substrate 34 in which the first n⁻-type silicon carbide epitaxial layer 2 is stacked on the n⁺-type starting substrate 1 containing an n-type silicon carbide is prepared (refer to FIG. 1). The silicon carbide semiconductor substrate 34 may be purchased, or the n⁺-type starting substrate 1 alone may be purchased and the first n⁻-type silicon carbide epitaxial layer 2 may be formed thereon by epitaxial growth to thereby form the silicon carbide semiconductor substrate 34 above. In this instance, the first n⁻-type silicon carbide epitaxial layer 2 containing silicon carbide is grown on the first main surface of the n⁺-type starting substrate 1, while an n-type dopant, for example, nitrogen atoms, is doped (first process).

Next, dopant ions are selectively implanted at the surface of the silicon carbide semiconductor substrate 34. As a result, in the silicon carbide semiconductor substrate 34, dopant regions (for example, the p-type base layer 3, the first p⁺-type regions 4, the second p⁺-type regions 5, the second n⁻-type silicon carbide layer 6, the n⁺-type source regions 7, the p⁺⁺-type contact regions 8, etc.) are formed. These dopant regions are formed as follows.

First, on the surface of the first n⁻-type silicon carbide epitaxial layer 2, a non-depicted resist mask having predetermined openings is formed by a photolithographic technique. Subsequently, a p-type dopant, for example, aluminum atoms, is ion-implanted by an ion-implantation method, whereby in the first n⁻-type silicon carbide epitaxial layer 2, the first p⁺-type regions 4 and the second p⁺-type regions 5 with a thickness of about 0.6 μm are formed having a dopant concentration in a range of, for example, 1×10¹⁸/cm³ to 5×10¹⁸/cm³.

Next, on the surface of the first n⁻type silicon carbide epitaxial layer 2, a non-depicted resist mask having predetermined openings is formed by a photolithographic technique. Subsequently, the second n⁻-type silicon carbide layer 6 having a thickness of about 0.7 μm and doped with an n-type dopant such as nitrogen is formed by an ion-implantation method and has a dopant concentration in a range of, for example, 1×10¹⁷/cm³ to 3×10¹⁷/cm³. The second n⁻-type silicon carbide layer 6 may be formed on the surface of the first n⁻-type silicon carbide epitaxial layer 2 by epitaxial growth.

Next, on the surface of the first n⁻type silicon carbide epitaxial layer 2, a non-depicted resist mask having predetermined openings is formed by a photolithographic technique. Subsequently, the p-type base layer 3 having a thickness of about 0.5 μm and a dopant concentration in a range of, for example, 1×10¹⁷/cm³ to 5×10¹⁷/cm³ is formed by an ion-implantation method (second process). The p-type base layer 3 may be formed on the surface of the second n⁻-type silicon carbide layer 6 by epitaxial growth.

Next, on the surface of the p-type base layer 3, a non-depicted resist mask having predetermined openings is formed by a photolithographic technique. Subsequently, an n⁺-type source layer (constituting the n⁺-type source regions 7) having a thickness of about 0.5 μm and a dopant concentration in a range of, for example, 1×10¹⁹/cm³ to 3×10¹⁹/cm³ is formed by an ion-implantation method (third process).

Next, an implantation mask having predetermined openings is formed and a p-type dopant such as aluminum is ion-implanted in portions of the n⁺-type source layer (7) and in portions of the p-type base layer 3, whereby the p⁺⁺-type contact regions 8 having a dopant concentration in a range of, for example, 1×10²⁰/cm³ to 3×10²⁰/cm³ are formed (fourth process).

Next, a heat treatment under an inert gas atmosphere of about 1750 degrees C. is performed, implementing an activation treatment for the dopant regions formed by ion implantation. The ion-implanted regions may be activated collectively by a single session of the heat treatment or may be activated by performing the heat treatment each time ion implantation is performed.

Next, on the surfaces of the n⁺-type source regions 7, a trench formation mask having predetermined openings is formed by photolithography using, for example, an oxide film. The trenches 18, which penetrate through the n⁺-type source regions 7 and the p-type base layer 3 and reach the second p⁺-type regions 5 are formed by dry etching (fifth process). Next, the trench formation mask is removed.

After the trenches 18 are formed, isotropic etching for removing damage of the trenches 18 and/or sacrificial oxidation for rounding the bottoms of the trenches 18 and corners of the openings of the trenches 18 may be performed. The isotropic etching or the sacrificial oxidation alone may be performed. Further, the sacrificial oxidation may be performed after the isotropic etching is performed. As a result, the silicon carbide surface may be clean and the corners are rounded, thereby enabling suppression of a concentration of electric field at the bottoms and the openings of the trenches 18.

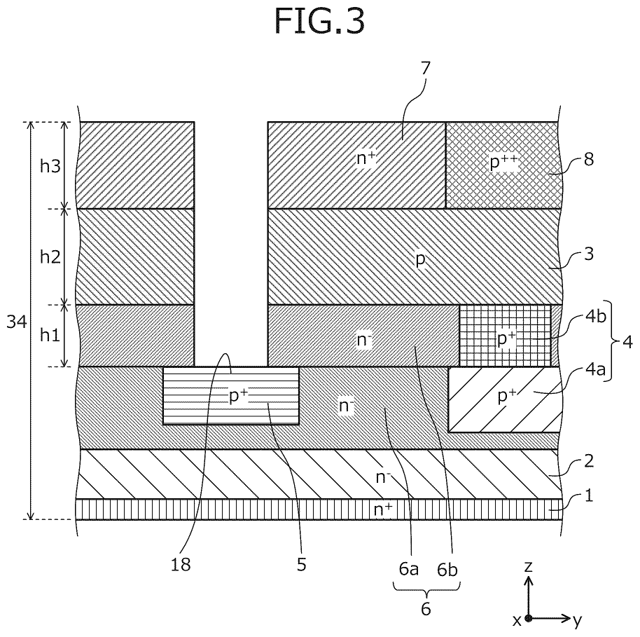

In the first embodiment, the n-type embedded channels 21 are formed by obliquely implanting dopant ions (oblique implantation) (sixth process). FIGS. 3, 4, 5, 6, and 7 are cross-sectional views schematically depicting states of the silicon carbide semiconductor device according to the first embodiment during manufacture. In FIGS. 3 to 7, formation of the n-type embedded channels 21 is primarily described. First, a state in which the trenches 18 are formed is depicted in FIG. 3.

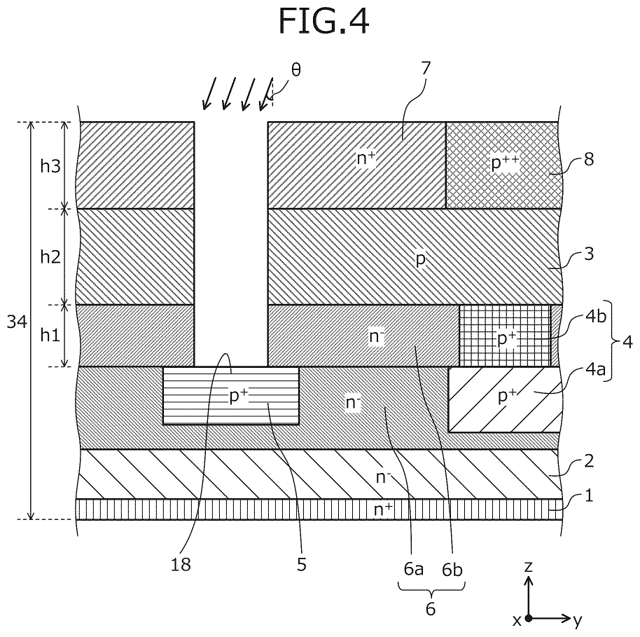

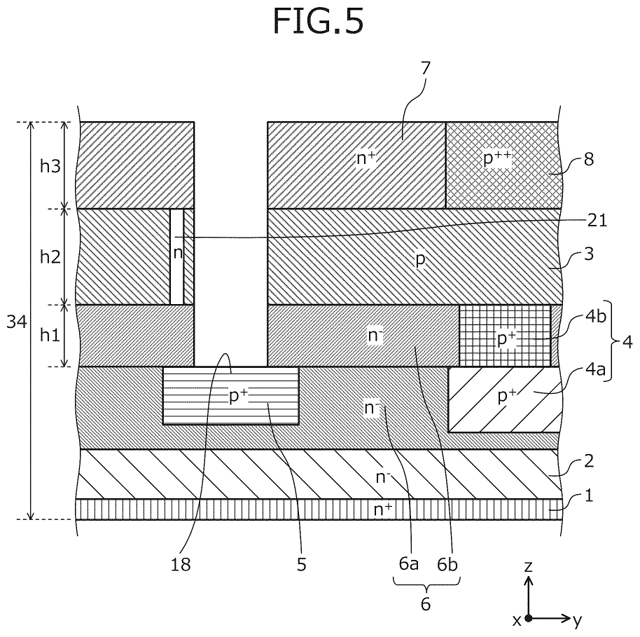

Next, as depicted in FIG. 4, dopant ions are obliquely implanted at an angle θ in a range of 15 degrees to 60 degrees with respect to sidewalls of the trenches 18 (oblique implantation). As a result, as depicted in FIG. 5, one of the n-type embedded channels 21 is formed at a first sidewall of each of the trenches 18.

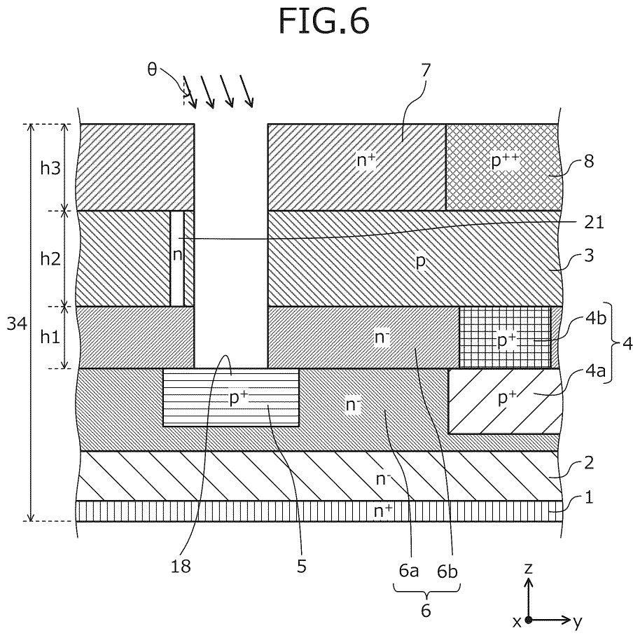

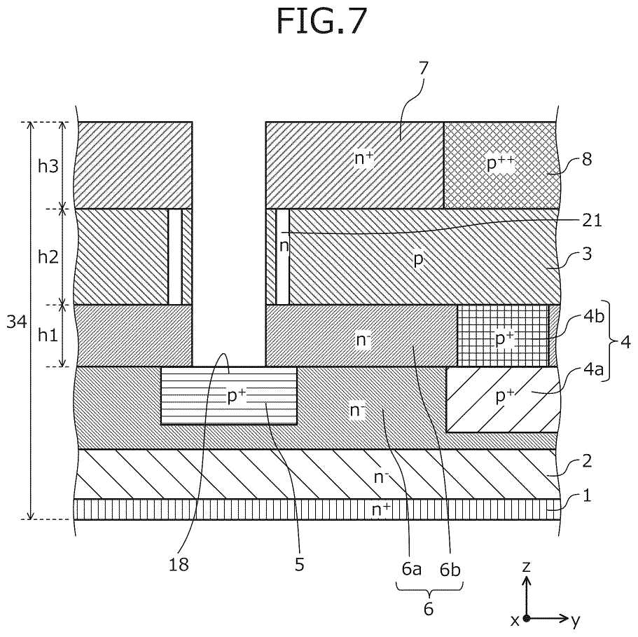

Next, as depicted in FIG. 6, dopant ions are obliquely implanted at the angle θ in the range of 15 degrees to 60 degrees with respect to sidewalls of the trenches 18, in a direction opposite to that in FIG. 4. As a result, as depicted in FIG. 7, one of the n-type embedded channels 21 is formed at a second sidewall of each of the trenches 18. Thus, the dopant profile in an orthogonal direction from a vicinity of an interface of any of the gate insulating films 9 may be SiO₂/p-type/n-type/p-type.

Preferably, the dopant ions may be phosphorus or arsenic. Furthermore, to adjust the dopant concentration of the first p-type base layer portions 3a that are relatively closer to the interface, aluminum (Al) may be obliquely implanted as dopant ions, at the angle θ in the range of 15 degrees to 60 degrees with respect to sidewalls of the trenches 18.

Next, the gate insulating films 9, the gate electrodes 10, the interlayer insulating film 11, and the ohmic electrodes 13 are formed. These are formed as follows. Along the surfaces of the n⁺-type source regions 7 and the p⁺⁺-type contact regions 8 and the bottoms and the sidewalls of the trenches 18, the gate insulating films 9 are formed (seventh process). The gate insulating films 9 may be formed by thermal oxidation of a temperature of about 1300 degrees C. under a gas atmosphere containing oxygen. Further, the gate insulating films 9 may be formed by a deposition method by a chemical reaction such as that for a high temperature oxide (HTO).

Next, a polycrystalline silicon layer doped with, for example, phosphorus atoms, is provided on the gate insulating films 9. The polycrystalline silicon layer may be formed so as to be embedded in the trenches 18. The polycrystalline silicon layer is patterned by photolithography and portions thereof are left in the trenches 18, thereby forming the gate electrodes 10 (eighth process).

Next, for example, a phosphate glass is deposited so to cover the gate insulating films 9 and the gate electrodes 10 and have a thickness of about 1 μm, whereby the interlayer insulating film 11 is formed. Next, the interlayer insulating film 11 and the gate insulating films 9 are patterned by photolithography, thereby forming contact holes in which the n⁺-type source regions 7 and the p⁺⁺-type contact regions 8 are exposed. Next, in the contact holes and on the interlayer insulating film 11, a conductive film constituting the ohmic electrodes 13 is formed by depositing, for example, nickel by, for example, a sputtering method (ninth process). Next, the conductive film and the silicon carbide are selectively reacted by a heat treatment of a temperature of about 1000 degrees C. and thereafter, unreacted portions of the conductive film are selectively removed, leaving only the ohmic electrodes 13 in the contact holes, whereby the ohmic electrodes 13 are in contact with the n⁺-type source regions 7 and the p⁺⁺-type contact regions 8.

Next, a Ti film and a TiN film are sequentially deposited in the sequence stated. At the surfaces of the ohmic electrodes 13 and the interlayer insulating film 11, the Ti film is deposited and thereafter, at the surface of the Ti film, the TiN film is deposited. For example, the Ti film has a thickness in a range of 10 nm to 100 nm, and the TiN film has a thickness in a range of 50 nm to 200 nm. Next, the Ti film and the TiN film are annealed (heat treated), thereby forming the barrier metal.

Next, for example, a metal film constituting the source electrode pad is deposited on the barrier metal by a sputtering method. Next, the metal film is selectively removed, thereby forming the source electrode pad (not depicted).

Next, the front surface of the n⁺-type starting substrate 1 is covered and protected by a protective film (not depicted) and thereafter, the n⁺-type starting substrate 1 may be ground from the back surface thereof, whereby the n⁺-type starting substrate 1 is thinned to a product thickness.

Next, on a second main surface of the n⁺-type starting substrate 1, conductive films constituting the drain electrode 14, for example, a mmolybdenum film and a nickel film are deposited successively by, for example, a sputtering method. Thereafter, a heat treatment, for example, laser annealing is performed, causing the n⁺-type starting substrate 1 and the conductive film to react and form an ohmic junction, thereby forming the drain electrode (tenth process) 14.

Next, on the surface of the drain electrode 14, for example, titanium, nickel, and gold are sequentially deposited in the order stated as a trench electrode pad. Thus, as described, the silicon carbide semiconductor device depicted in FIG. 1 is completed.

As described above, according to the silicon carbide semiconductor device according to the first embodiment and the method of manufacturing the silicon carbide semiconductor device according to the first embodiment, the dopant profile in an orthogonal direction from a vicinity of an interface of any of the gate insulating films is SiO₂/p-type/n-type/p-type. As a result, near the gate insulating film interface, an embedded channel with high mobility is apart from a channel with low mobility near the interface. Thus, carriers of the embedded channels are not attracted to the interface channels, which have low mobility, and due to the separated embedded channels, the channel resistance is lower than that of the conventional inversion carrier channel and a low on-resistance and high mobility may be maintained.

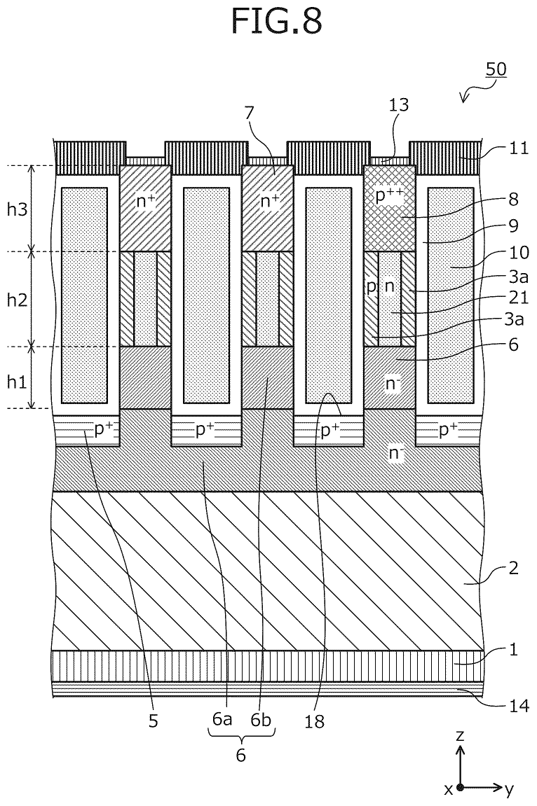

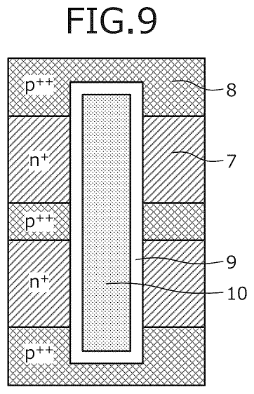

FIG. 8 is a cross-sectional view depicting a structure of the silicon carbide semiconductor device according to a second embodiment. FIG. 8 depicts only the active region through which a main current of the trench-type MOSFET 50 flows. FIG. 9 is a top view depicting the structure of the semiconductor device according to the second embodiment. In the second embodiment, the trench-type MOSFET 50 is assumed to be an FinFET structure. The FinFET structure is a so-called double gate structure in which a width between any adjacent two of the trenches 18 is narrow (not more than 300 nm), one channel (n-type inversion layer) formed in nearly an entire area of the p-type base layer 3 between the any adjacent two of the trenches 18 is sandwiched from both side surfaces thereof by MOS gates.

As depicted in FIG. 8, in the second embodiment as well, the n-type embedded channels 21 are provided in the p-type base layer 3. Each of the n-type embedded channels 21 has an upper surface in contact with the n⁺-type source regions 7 or the p⁺⁺-type contact regions 8 and a lower surface in contact with the second n⁻-type silicon carbide layer 6. Each of the n-type embedded channels 21 separates the p-type base layer 3 into a first p-type base layer portion 3a relatively closer to the gate insulating film 9 of one of the trenches 18 adjacent thereto and a first p-type base layer portion 3a relatively closer to the gate insulating film 9 of the other one of the trenches 18 adjacent thereto. In other words, in the direction in which the trenches 18 are arranged (the y-direction), one of the gate insulating films 9, one of the first p-type base layer portions 3a, one of the n-type embedded channels 21, another one of the first p-type base layer portions 3a, and another one of the gate insulating films 9 are repeatedly arranged in the sequence stated. Thus, the structure is a completely embedded-type channel structure in which the dopant profile in an orthogonal direction from a vicinity of an interface of any of the gate insulating films 9 is SiO₂/p-type/n-type/p-type/SiO₂.

Further, similar to the first embodiment, the second p⁺-type regions 5 are selectively provided in the second n⁻-type silicon carbide layer 6. The lower ends of the second p⁺-type regions 5 are positioned closer to the n⁺-type starting substrate 1 than are the bottoms of the trenches 18. The second p⁺-type regions 5 are formed, respectively, at positions facing the bottoms of the trenches 18 in the depth direction z. The width of each of the second p⁺-type regions 5 is about a same width as that of each of the trenches 18. The bottoms of the trenches 18 may reach the second p⁺-type regions 5 or may be positioned in the second n⁻-type silicon carbide layer 6 between the p-type base layer 3 and the second p⁺-type regions 5 without being in contact with (being apart from) the second p⁺-type regions 5. The second p⁺-type regions 5 are doped with, for example, aluminum (Al).

In the FinFET structure, a distance between the first p-type base layer portions 3a relatively closer to the gate insulating films 9 is short and thus, an enhanced type is possible even without the second p-type base layer portions 3b sandwiched by the n-type embedded channels 21. For example, preferably, an interval (width of a mesa portion) between the trenches 18 may be about 200 nm. Further, preferably, the dopant concentration of the n-type embedded channels 21 may be about 5×10¹⁷/cm³ and the dopant concentration of the first p-type base layer portions 3a may be about 1×10¹⁸/cm³.

In the second embodiment, preferably, the height h1 of the upper second n⁻-type silicon carbide layer 6 b may be about 0.5 μm or less, the height h2 of the first p-type base layer portions 3a and the n-type embedded channels 21 may be about 0.85 μm or less, and the height h3 of the n⁺-type source regions 7 and the p⁺⁺-type contact regions 8 may be about 0.45 μm or less.

As described above, according to the silicon carbide semiconductor device according to the second embodiment and the method of manufacturing the silicon carbide semiconductor device according to the second embodiment, the structure is a completely embedded type channel structure in which the dopant profile in an orthogonal direction from a vicinity of an interface of any of the gate insulating films is SiO₂/p-type/n-type/p-type/SiO₂ and thus, effects similar to those of the first embodiment are obtained. Furthermore, in the second embodiment, an enhanced type is possible even without the second p-type base layer portions sandwiched by the n-type embedded channels.

In the foregoing, in the present disclosure, while an instance in which a main surface of the silicon carbide substrate containing silicon carbide is assumed to be (0001) plane and on the (0001) plane, MOS is configured is described as an example, without limitation hereto, various modifications are possible such as the wide band gap semiconductor, surface orientation of the main surface of the substrate, and the like used. Further, in the embodiments of the present disclosure, while a trench-type MOSFET is described as an example, without limitation hereto, the present disclosure is applicable to semiconductor devices of various types of configurations such as MOS-type semiconductor devices like planar-type MOSFETs and IGBTs.

The silicon carbide semiconductor device and the method of manufacturing the silicon carbide semiconductor device according to the present disclosure achieve an effect in that the dopant profile in an orthogonal direction from a vicinity of an interface of a gate insulating film is SiO2/p-type/n-type/p-type and the RonA-Vth tradeoff may be improved.

As described above, the silicon carbide semiconductor device and the method of manufacturing the silicon carbide semiconductor device according to the present disclosure are useful for high-voltage semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate containing silicon carbide, the semiconductor substrate having a first main surface and a second main surface opposite to each other;
a first semiconductor region of a first conductivity type, provided in the semiconductor substrate;
a second semiconductor region of a second conductivity type, provided in the semiconductor substrate between the first main surface and the first semiconductor region;
a plurality of third semiconductor regions of the first conductivity type, provided selectively in the semiconductor substrate between the first main surface and the second semiconductor region;
a plurality of fourth semiconductor regions of the second conductivity type, provided selectively in the semiconductor substrate between the first main surface and the second semiconductor region, a dopant concentration of the plurality of fourth semiconductor regions being higher than a dopant concentration of the second semiconductor region;
a plurality of fifth semiconductor regions of the first conductivity type, provided selectively in the second semiconductor region;
a plurality of trenches penetrating through the plurality of third semiconductor regions and the plurality of second semiconductor region and reaching the first semiconductor region;
a plurality of gate insulating films provided in the plurality of trenches, respectively;
a plurality of gate electrodes provided in the plurality of trenches, via the plurality of gate insulating films, respectively;
a first electrode connected to the plurality of fourth semiconductor regions and the plurality of third semiconductor regions; and
a second electrode provided at the second main surface of the semiconductor substrate, wherein
the plurality of fifth semiconductor regions separates the second semiconductor region into a plurality of first second-semiconductor-regions and a plurality of second second-semiconductor-regions, each of the plurality of first second-semiconductor-regions, but not the plurality of second second-semiconductor-regions, being directly adjacent to one of the plurality of gate insulating films, and
a thickness of each of the plurality of first second-semiconductor-regions is in a range of 30 nm to 100 nm, such that a carrier concentration of the plurality of fifth semiconductor regions is controllable by a potential of the plurality of gate electrodes, to thereby control a current between the first electrode and the second electrode.

2. The silicon carbide semiconductor device according to claim 1, wherein
each of the plurality of fifth semiconductor regions is in contact with one of the plurality of third semiconductor regions and the first semiconductor region.

3. The silicon carbide semiconductor device according to claim 1, wherein
the plurality of trenches is arranged, one after another, in a first direction, and
ends of the plurality of first second-semiconductor-regions in the first direction are connected to ends of the plurality of second second-semiconductor-regions in the first direction.

4. The silicon carbide semiconductor device according to claim 1, wherein
the second conductivity type is a p type, and
the potential of the plurality of gate electrodes is controllable to be positive with respect to the first electrode, so that the silicon carbide semiconductor device is in a conductive state.

5. The silicon carbide semiconductor device according to claim 1, wherein
a voltage of the plurality of gate electrodes is controllable to be the same as that of the first electrode, so that the silicon carbide semiconductor device enters an off state.

6. A silicon carbide semiconductor device, comprising:
a semiconductor substrate containing silicon carbide, the semiconductor substrate having a first main surface and a second main surface opposite to each other;
a first semiconductor region of a first conductivity type, provided in the semiconductor substrate;
a second semiconductor region of a second conductivity type, provided in the semiconductor substrate between the first main surface and the first semiconductor region;
a plurality of third semiconductor regions of the first conductivity type, provided selectively in the semiconductor substrate between the first main surface and the second semiconductor region;
a plurality of fourth semiconductor regions of the second conductivity type, provided selectively in the semiconductor substrate between the first main surface and the second semiconductor region, a dopant concentration of the plurality of fourth semiconductor regions being higher than a dopant concentration of the second semiconductor region;
a plurality of fifth semiconductor regions of the first conductivity type, provided selectively in the second semiconductor region;
a plurality of trenches penetrating through the plurality of third semiconductor regions and the plurality of second semiconductor region and reaching the first semiconductor region;
a plurality of gate insulating films provided in the plurality of trenches, respectively;
a plurality of gate electrodes provided in the plurality of trenches, via the plurality of gate insulating films, respectively;
a first electrode connected to the plurality of fourth semiconductor regions and the plurality of third semiconductor regions; and
a second electrode provided at the second main surface of the semiconductor substrate, wherein
the silicon carbide semiconductor device has a double gate structure in which one channel formed in an entire area of the second semiconductor region between adjacent two of the plurality of trenches, is sandwiched from both side surfaces thereof, by the adjacent two of the plurality of trenches, and
the plurality of fifth semiconductor regions separates the second semiconductor region into a plurality of first second-semiconductor-regions and a plurality of second second-semiconductor-regions, each of the plurality of first second-semiconductor-regions, but not the plurality of second second-semiconductor-regions, being directly adjacent to one of the plurality of gate insulating films.

7. A method of manufacturing a silicon carbide semiconductor device, the method comprising:
preparing a semiconductor substrate containing silicon carbide, the semiconductor substrate having a first main surface and a second main surface opposite to each other;
as a first process, forming a first semiconductor region of a first conductivity type, in the semiconductor substrate;
as a second process, forming a second semiconductor region of a second conductivity type in the semiconductor substrate, between the first main surface of the semiconductor substrate and the first semiconductor region;
as a third process, selectively forming a plurality of third semiconductor regions of the first conductivity type in the semiconductor substrate, between the first main surface of the semiconductor substrate and the second semiconductor region;
as a fourth process, selectively forming a plurality of fourth semiconductor regions of the second conductivity type in the semiconductor substrate, between the first main surface of the semiconductor substrate and the second semiconductor region, a dopant concentration of the plurality of fourth semiconductor regions being higher than dopant concentration of the second semiconductor region;
as a fifth process, forming a plurality of trenches penetrating through the plurality of third semiconductor regions and the second semiconductor region and reaching the first semiconductor region;
as a sixth process, selectively forming a plurality of fifth semiconductor regions of the first conductivity type, in the second semiconductor region;
as a seventh process, forming a plurality of gate insulating films in the plurality of trenches, respectively;
as an eighth process, forming a plurality of gate electrodes in the plurality of trenches, via the plurality of gate insulating films, respectively;
as a ninth process, forming a first electrode electrically connected to the plurality of fourth semiconductor regions and the plurality of third semiconductor regions; and
as a tenth process, forming a second electrode at the second main surface of the semiconductor substrate, wherein
the plurality of fifth semiconductor regions separates the second semiconductor region into a plurality of first second-semiconductor-regions and a plurality of second second-semiconductor-regions, each of the plurality of first second-semiconductor-regions, but not the plurality of second second-semiconductor-regions, being directly adjacent to one of the plurality of gate insulating films, and
in the sixth process, a thickness of each of the plurality of first second-semiconductor-regions is in a range of 30 nm to 100 nm, such that a carrier concentration of the plurality of fifth semiconductor regions is controllable by a potential of the plurality of gate electrodes, to thereby control a current between the first electrode and the second electrode.

8. The method of manufacturing according to claim 7, wherein
the sixth process includes obliquely implanting phosphorus ions at an angle in a range of 15 degrees to 60 degrees with respect to sidewalls of the plurality of trenches, thereby forming the plurality of fifth semiconductor regions.

9. The method of manufacturing according to claim 7, wherein
the sixth process includes obliquely implanting arsenic ions at an angle in a range of 15 degrees to 60 degrees with respect to sidewalls of the plurality of trenches, thereby forming the plurality of fifth semiconductor regions.

10. The method of manufacturing according to claim 7, further comprising
as an eleventh process, obliquely implanting aluminum ions in the plurality of first second-semiconductor-regions, at an angle in a range of 15 degrees to 60 degrees with respect to sidewalls of the plurality of trenches.
